(19) United States
(12) Patent Application Publication
(10) Pub. No.: US 2003/0222334 A1
(43) Pub. Date: Dec. 4, 2003

(54) Display apparatus and producing method therefor

(75) Inventors: Sotomitsu Ikeda, Kanagawa (JP); Takao Yonehara, Kanagawa (JP); Kiyofumi Sakaguchi, Kanagawa (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 10/447,156

(22) Filed: May 29, 2003

(30) Foreign Application Priority Data
May 30, 2002 (JP) 2002-157577

(51) Int. Cl. H01L 21/00; H01L 21/30; H01L 23/02

(52) U.S. Cl. 257/678; 438/455; 438/458

(57) ABSTRACT

The invention provides a light, thin flexible display of a high performance.

A display element unit including plural display elements is laminated with a semiconductor film bearing an image forming switching element unit for driving the display elements. A semiconductor film is formed on a separating layer of a semiconductor substrate, and a switching circuit unit is formed thereon. Then the semiconductor film is separated at the separating layer, and an image display unit is laminated thereon to obtain a light, thin flexible display apparatus.

### BACKGROUND OF THE INVENTION

1. Field of the Invention

The present invention relates to a display apparatus and a method for producing the same, and more particularly to a thin flexible display apparatus and a method for producing the same.

2. Related Background Art

With the recent progress in information equipment, there have been increasing needs for a thin display apparatus of a low electric power consumption, and display apparatuses are being actively developed in order to meet such needs. In particular there have been proposed various display media which are similar to paper (printed paper) in shape, and of which display is electrically rewritable, under names of a digital paper, a paper-like display, an electronic book etc. For example, Japanese Patent Application Laid-Open No. 11-502950 discloses a configuration of an electronic book constituted by plural sheet-shaped page displays.

In such sheet-shaped display, in order to attain a shape close to paper, it is not only necessary to form a thin film transistor circuit for switching pixels, namely so-called TFT switching circuit, close to the display pixels, but also to form a scan line drive circuit, constituted for example by a sample hold circuit, a shift register etc. and peripheral circuits such as a data line drive circuit for driving the TFT switching circuit on a same substrate which bears the pixels or to embed such circuits in such substrate.

This is particularly essential in an electronic book constituted by plural sheet-shaped displays. Unless peripheral circuits, particularly so-called driving ICs including the scan line drive circuit and the data line drive circuit, are positioned in the same sheet bearing the pixel units, there are required bondings of an enormous number between a member supporting plural sheets and provided with such peripheral circuits, for example a member corresponding to a rear cover of the book, and each display sheet. For example in case each display sheet includes pixels arranged in a matrix of X rows and Y columns, there have to be formed bondings of a number of at least X+Y (2400 in case of a color VGA format) between the drive circuit and each display sheet, and such bondings have to be made on a side (binding edge) of the display sheet.

In order to arrange all the bondings to the TFT switching circuit on one side of a display sheet, there is required a very large area for pulling-around of such bondings, and, as a result, a proportion of the display area may have to be reduced on the display sheet. Also as the amount of bondings with a member bearing the peripheral circuit becomes enormous, there increases a probability of connection failure. Such probability of connection failure will increase further in a configuration where each display sheet is detachable from a rear cover sheet.

It is therefore extremely important, as will be easily understood, particularly in an electronic book, to position at least a part of the peripheral circuits in the vicinity of the pixels, and to reduce the number of bondings to the member, other than the display sheet, bearing a remainder of the peripheral circuits, a power supply circuit etc. In fact, in case the drive IC is positioned on the substrate bearing the pixels, the number of the bondings to the exterior of the substrate can be made about 100 or less in the color VGA format, thus being significantly less than the number of bondings (2400 or more) in case the drive IC is positioned outside the substrate.

Naturally also in the display apparatus of the conventional solid configuration, even in case all the four sides of the substrate bearing the pixels are available for bondings, there is also required an enormous number of bondings with a peripheral circuit chip such as an IC or an LSI unless the peripheral circuits are provided in the vicinity of the pixels, namely on the substrate bearing pixels. Also such bondings are made by a TAB (tape automated bonding) of which pitch is more or less limited to about 130 ppi and such bonding is not applicable to a display apparatus having a higher resolution.

Therefore, in order to avoid such drawbacks and to increase the productivity thereby providing a display apparatus of a lower cost, attention is being paid to so-called an active matrix display apparatus integral with the drive circuit, in which the peripheral circuits are formed on the same substrate bearing the TFT switching circuit.

Particularly in case a polycrystalline silicon film is utilized for the TFT switching circuit, it is possible to easily form peripheral circuits of a high operation speed on the same substrate, because such polycrystalline silicon device has a mobility of about 100 times of that in an amorphous silicon device (for example Japanese Patent Application Laid-open No. 5-333371).

However, in order to deposit a polycrystalline silicon film and to form a semiconductor circuit or an integrated semiconductor circuit thereon, there is required a high temperature process of 900° C. or higher, and it is necessary to employ an expensive substrate such as of silicon or quartz.

In order to circumvent such drawbacks, a low-temperature polycrystalline silicon device forming process, capable of utilizing an inexpensive glass substrate, was proposed in late 1980's and commercially utilized from about 1995. In this process, an amorphous silicon film, that can be formed at a lower temperature, is formed by plasma CVD on a substrate, and is subjected to an excimer laser annealing (ELA) in a necessary portion to locally crystallize the silicon.

However, such low-temperature process still requires a process temperature reaching 600° C. at maximum, and is therefore not applicable to a plastic substrate in place for a glass substrate, in order to achieve flexibility, a lighter weight and a resistance to destruction. Particularly in a paper-like display or an electronic book aiming at a display close to paper in shape, the display area is principally formed by a plastic-based material of low thermal resistance, so that it is necessary to form the circuits with a process of as a low temperature as possible.

As a first method for forming a circuit by a low-temperature process on a plastic substrate, as disclosed by D. Gundlach et al., Tech. Dig. -Int. Electron Devices Meet. (1999), pp.111-114 or by T. N. Jackson et at., SID 00 Dig. (2000), pp.411-414, there is known a method of utilizing an organic semiconductor that can be formed by a method under normal temperature and normal pressure, such as a spin coating or a printing. However, since the organic semiconductor material has a low carrier mobility, such process is may be applicable to a switching circuit but is not applicable to a peripheral circuit requiring a high speed.

Also as a second method, S. D. Theiss et al. discloses, in Tech Dig. -Int. Electron Devices Meet. (1998), pp.257-260, a method of forming a polycrystalline silicon TFT on a plastic (PET) substrate utilizing a process of at first forming a silicon oxide film for a thermal diffusion by plasma CVD on a substrate, then forming an amorphous silicon film thereon by a DC sputtering, and forming polycrystals in a desired portion only by repeating a local repeated-pulse excimer laser annealing. This method, however, may be associated with a low productivity because the circuits are formed one by one in succession by repeating the pulsed annealing.

Also as a third method, S. Drobac, SID 99 Dig. (1999), pp.12-16 discloses a process (called FSA) of forming semiconductor circuits or integrated semiconductor circuits on a single-crystal silicon wafer, then dispersing the separated chips of such circuits in a fluid and immersing a plastic substrate having a recess in a predetermined position, whereby the chip of single-crystal silicon fits in such recess by an auto-aligning manner.

Such method has no concern on the device characteristics because the single-crystal silicon can be utilized. However, there may be involved a loss in the yield of the auto-aligned fitting step of the silicon chips, and a limitation in the circuit designing required for efficiently fitting the chip (connecting portion of the chip with the substrate being geometrically symmetrical linearly or rotationally).

Also as a fourth method, S. Utsunomiya et al., SID 00 Dig (2000), pp.916-919, discloses a method (called SUFTLA) of depositing a polycrystalline silicon layer across an amorphous silicon sacrifice layer on a quartz substrate for growing, then forming thereon a semiconductor circuit such as a TFT, then irradiating the growing substrate from the rear side thereof with an excimer laser thereby crystallizing or abrading the amorphous silicon layer and facilitating separation of the polycrystalline silicon layer, including the semiconductor circuit, from the growing substrate, and transferring thus separated polycrystalline silicon layer including the semiconductor circuit to a desired supporting substrate.

In this method, the supporting substrate may be composed of any material, and can be of a low-melting material such as plastics. However, unless the irradiation with the excimer laser is executed uniformly on the rear surface of the growing substrate, there may result an uneven peeling in the course of the separating step, thus damaging the semiconductor circuit or deteriorating the device characteristics. Such drawback will occur more frequently as an area of transfer increases.

Also as a fifth method similar to the fourth method, Japanese Patent Application Laid-open No. 9-312349 discloses a method of depositing a single-crystal silicon layer across a porous layer on a semiconductor substrate, then forming a desired semiconductor circuit thereon, adhering a desired supporting substrate on the semiconductor substrate, and separating the semiconductor substrate at the porous layer by an external (tensile) force thereby transferring the semiconductor circuit onto the supporting substrate. In this method, however, since the separating step is executed by an external tensile force, a local strain may be induced by a part of the semiconductor circuit, thereby damaging the semiconductor circuit or deteriorating the device characteristics. Such drawback will occur more frequently as an area of transfer increases.

Thus, the preparation of a display apparatus including a highly precise semiconductor circuit on a substrate of an inferior heat resistance by such conventional method has been associated with drawbacks of a deterioration of the characteristics of the circuit devices and a loss in the production yield. Also in case of transferring a thin semiconductor film onto a substrate and then forming an image display unit, a process for forming the image display unit is restricted by the property of the substrate, for example an upper limit temperature of the process for forming image display unit or a thermal shrinkage of the substrate in such process. Furthermore, the use of such substrate increase the thickness of the image display apparatus, whereby the flexibility thereof is limited.

### SUMMARY OF THE INVENTION

In consideration of the foregoing, an object of the present invention is to provide a display apparatus which is lighter and thinner and has flexibility, by forming a display element unit on a semiconductor film on which a circuit unit is formed, and a producing method therefor.

The aforementioned objective can be attained, according to the present invention, by a display apparatus formed by laminating a display element unit constituted by plural display elements, and a semiconductor film which is separated from a separating layer formed on a substrate and on which formed are plural image forming switching elements for driving the display elements.

Also a producing method of the present invention for producing the display apparatus includes a step of forming a semiconductor film on a substrate having a separating layer, a step of forming image forming switching elements on the semiconductor film, a step of forming an image display unit on the semiconductor film, a step of forming an upper protective film on the image display unit, a step of peeling and separating the semiconductor film, the image display unit and the upper protective film from the substrate at the separating layer, and a step of forming a lower protective film at a side of the semiconductor film.

Also a producing method of the present invention for producing the display apparatus includes a step of forming a semiconductor film on a substrate having a separating layer, a step of forming image forming switching elements and a peripheral circuit unit on the semiconductor film, a step of forming an image display unit on the semiconductor film, a step of forming an upper protective film on the image display unit, a step of peeling and separating the semiconductor film, the image display unit and the upper protective film from the substrate at the separating layer, and a step of forming a lower protective film at a side of the semiconductor film.

Also a producing method of the present invention for producing the display apparatus includes a step of forming a semiconductor film on a substrate having a separating layer, a step of forming image forming switching elements or image forming switching elements and a peripheral circuit unit on the semiconductor film, a step of forming notched grooves on the semiconductor film thereby dividing the semiconductor film into plural areas, a step of forming an image display unit in each divided area of the semiconductor film, a step of forming an upper protective film on the image display unit, a step of peeling and separating the semiconductor film, the image display unit and the upper protective film from the substrate at the separating layer, and a step of forming a lower protective film at a side of the semiconductor film.

Also a producing method of the present invention for producing the display apparatus includes a step of forming a first semiconductor film on a first substrate having a first separating layer, a step of forming a circuit unit including at least image forming switching elements on the first semiconductor film, a step of adhering a temporary substrate onto the first semiconductor film, a step of separating the first substrate from the separating layer, a step of forming a second semiconductor film on a second substrate having a second separating layer, a step of forming a peripheral circuit unit on the second semiconductor film, a step of adjoining the first semiconductor film on the temporary substrate and the second semiconductor film on the second substrate, a step of separating the temporary substrate, a step of forming an image display unit on the first semiconductor substrate after the separation of the temporary substrate, a step of forming an upper protective film on the image display unit, a step of separating the second substrate at the second separating layer, and a step of forming a lower protective film at a side of the semiconductor film.

The present invention, not requiring the flexible substrate as in the conventional technologies, can realize a thinner and more flexible display apparatus. Also a process temperature at the formation of the image display unit is not restricted by the flexible substrate, but depends on the reliability of the circuit formed on the semiconductor film (for example single-crystal silicon), so that a process up to about 1000° C. can be employed for forming the image forming unit. Therefore, various image display units can be realized with a high quality.

Other features and advantages of the present invention will be apparent from the following description taken in conjunction with the accompanying drawings, in which similar reference signs designate the same or similar parts through the figures.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIGS. 1A and 1B are views showing a first embodiment of a display apparatus of the present invention;

FIGS. 2A and 2B are views showing a second embodiment of the present invention;

FIGS. 3A and 3B are views showing a third embodiment of the present invention;

FIGS. 4A and 4B are views showing a fourth embodiment of the present invention;

FIGS. 5A and 5B are views showing a fifth embodiment of the present invention;

FIGS. 6A, 6B, 6C, 6D, 6E, 6F and 6G are views showing steps of an embodiment of a producing method for the display apparatus of the present invention;

FIGS. 7A, 7B, 7C, 7D, 7E, 7F, 7G and 7H are views showing steps of another embodiment of the producing method for the display apparatus of the present invention;

FIGS. 8A, 8B, 8C, 8D, 8E, 8F, 8G, 8H, 8I, 8J, 8K, 8L, 8M and 8N are views showing steps of still another embodiment of the producing method for the display apparatus of the present invention; and

FIG. 9 is a schematic cross-sectional view of a display apparatus prepared in an embodiment of the present invention.

### DESCRIPTION OF THE PREFERRED EMBODIMENTS

In the following the present invention will be explained by embodiments thereof with reference to the accompanying drawings.

(First Embodiment)

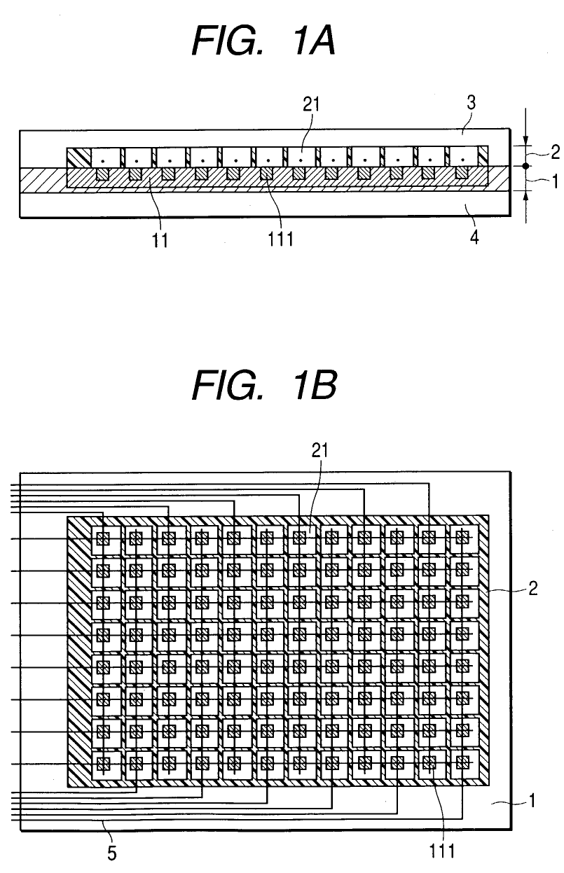

FIGS. 1A and 1B are respectively a cross-sectional view and a plan view, showing a first embodiment of the present invention. In FIGS. 1A and 1B, there are shown a semiconductor film having a circuit unit, a display element unit 2, an upper protective film 3, a lower protective film 4, wirings 5, an image forming switching circuit unit 11, display elements 21, and image forming switching elements 111.

The image forming switching circuit unit 11 includes plural switching element 111, which are provided respectively corresponding to the plural display elements 21. The plural switching elements 111 are respectively driven by image signals, thereby causing the display elements 21 to achieve an image display.

The display apparatus is constituted by laminating the display element unit 2 on the semiconductor film 1 on which the image forming switching circuit unit 11 is formed, and an upper surface is covered by the protective film 3 and a lower surface is covered by the protective film 4. The display elements 21 of the display element unit 2 are arranged in a matrix shape as shown in FIG. 1B.

The image forming switching circuit unit 11 is prepared by forming plural switching elements 111 on the semiconductor film 1 formed on-another substrate (separating substrate), and the display element unit and the upper protective film 3 are formed thereon. Such semiconductor film 1, display element unit 2 and upper protective film 3 are integrally formed and are peeled and separated from the separating substrate thereby realizing a laminate structure constituted by the upper protective film 3, the display element unit 2 and the semiconductor film 1. Thereafter the semiconductor film 1 is protective by the lower protective film 4 to complete the display apparatus. A producing process thereof will be explained later.

For the upper protective layer 3 and the lower protective layer 4, there can be employed for example a plastic material having flexibility. Also for at least either of the upper protective layer 3 and the lower protective layer 4, there is employed a translucent material for enabling extraction of light or selective reflection thereof, thus achieving an image display. Examples of the material for the upper protective layer 3 and the lower protective layer 4 include polycarbonate, denatured polyphenylene ether, polysulfone (PSF), polyethersulfone (PES), polyallylate (PAR), polyamidimide (PAI), polyetherimide (PEI), polyimide (PI), polyamide (PA), polyacetal (POM), polybutylene terephthalate (PBT), polyethylene terephthalate (PET), syndiotactic polystyrene (SPS), polyphenylene sulfide (PPS), polyether ether ketone (PEEK), a liquid crystal polymer, a fluorinated resin, and polyethernitrile (PEN).

The switching element 111 can be a three-terminal element represented by a MOS transistor, or a two-terminal element such as a MOS diode or an MIM non-linear element.

For the display element unit, there can be utilized a known display element such as liquid crystal display, organic EL display, inorganic EL display, electrochromic display, electrophoretic display, twisting ball display etc. The display element 21 has a structure including at least a pair of opposed electrodes for a voltage application, and an image display film positioned therebetween, and one of the electrodes is electrically connected with an electrode of the switching element.

In the embodiment shown in FIGS. 1A and 1B, the switching elements 111 are formed respectively corresponding to the pixels (display elements) 21 constituting the display element unit 21, but it is also possible to integrate plural switching elements 111 in such a manner that an integrated switching circuit controls plural pixels. Also the switching element 111 is positioned at the approximate center of the pixel 21, but such positional relationship is not restrictive, and the switching circuit may be positioned within a space between the pixels as already exercized in the known transmissive liquid crystal display apparatus.

Also in the embodiment shown in FIGS. 1A and 1B, there are only illustrated scan lines and data lines as the wirings 5, but it is naturally possible to add other necessary wirings such as a wiring for power supply to the display element unit 2, an off-state selecting wiring etc. The wirings 5 are connected to an unrepresented component which bears a peripheral circuit for driving the switching elements 111. Such connection may be fixed or may be made separable.

Also between the semiconductor film 1 having the circuit unit and the display element unit 2 which are mutually laminated, there may be formed an insulating layer, a planarizing layer and/or a wiring if necessary. For bonding the display element unit 2, the image forming switching circuit unit 111 and the wirings 5 there can be employed a known method such as contact holes, an anisotropic conductive film (ACF) or gold bumps.

As the present embodiment, in which the display element unit 2 is laminated on the semiconductor film 1, can dispense with the conventionally employed flexible substrate, thereby allowing to realize a lighter, thinner and more flexible display apparatus. Such configuration is particularly suitable for a sheet-shaped display of a shape close to paper. Also since the process temperature at the formation of the image display unit is not restricted by the substrate, there can be employed a process of a high temperature, whereby various image display units of a high quality can be realized.

(Second Embodiment)

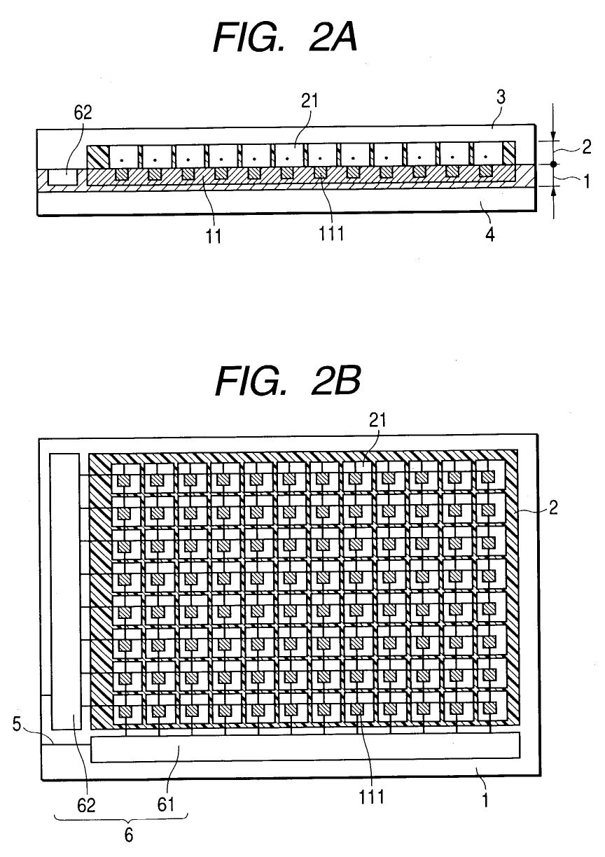

FIGS. 2A and 2B are respectively a cross-sectional view and a plan view, showing a second embodiment of the present invention, wherein components equivalent to those in FIGS. 1A and 1B are represented by like numbers and will not be explained further. In the present embodiment, a switching circuit unit 11 and a peripheral circuit unit 6 are formed on a same semiconductor film 1. The peripheral circuit unit 6 includes a scan line drive circuit 62 constituted by a shift register etc. for driving the image forming switching circuit unit 11, and a data line drive circuit 61 constituted by a shift register etc. Such scan line drive circuit and data line drive circuit serve to select the display elements 21 arranged in a matrix. Other configurations are similar to those in FIGS. 1A and 1B.

In the present embodiment, since the data line drive circuit 61 and the scan line drive circuit 62 are formed on the semiconductor film 1, the number of the bondings 5 connected to an unrepresented external peripheral circuit can be significantly reduced in comparison with the first embodiment. Therefore, in case of constituting the sheet-shaped image display unit in a configuration separable from the external peripheral circuit through the connector, it is possible to reduce the number of necessary bondings and to improve the reliability. The number of the bondings 5 shown in FIGS. 2A and 2B does not exactly represent the necessary number of the bondings.

In FIGS. 2A and 2B, the scan line drive circuit 62 and the data line drive circuit 61 are separated from the switching circuit unit 11, but these circuits may also be constructed as an integrated circuit. Also the semiconductor film 1 bearing the scan line circuit 62, the semiconductor film 1 bearing the data line drive circuit 61 and the semiconductor film 1 bearing the image forming switching circuit unit 11 are integrally shown in FIGS. 2A and 2B, but they may be formed separately and mutually bonded electrically.

In such case, unless the dimension of the display apparatus is excessively large, it is preferable to employ an integral circuit film since a cost for bonding the switching circuit and the drive circuits can be reduced. On the other hand, in case the dimension of the display apparatus is large, it is possible to further divide the peripheral circuit unit 6 and to suitably position plural members containing circuit films. Such configuration increases the flexibility.

(Third Embodiment)

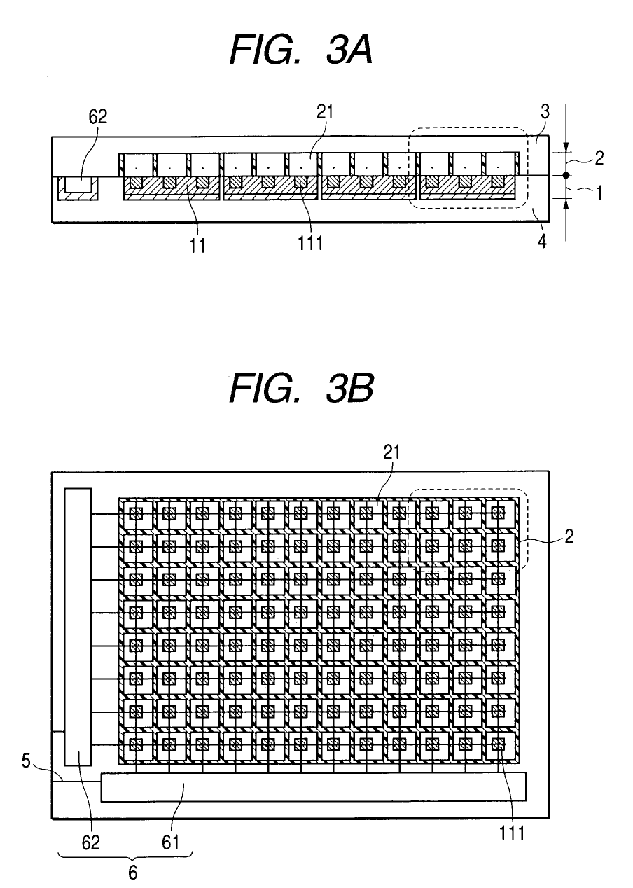

FIGS. 3A and 3B are respectively a cross-sectional view and a plan view, showing a third embodiment of the present invention, wherein components equivalent to those in FIGS. 1A through 2B are represented by like numbers and will not be explained further. In the first and second embodiments, the semiconductor film 1 bearing the image forming switching circuit unit 11 is formed by a single member on which all the switching elements 11 are formed, but, in the present embodiment, the semiconductor film 1 is divided into plural areas. Also a display element unit 2 is laminated on each of the divided areas of the semiconductor film 1.

More specifically, as indicated by broken lines in FIGS. 3A and 3B, the image forming switching circuit unit 11 is divided into plural semiconductor films 1 bearing the switching elements 111, and the display element unit 21 is also divided into plural areas. In a gap between thus divided semiconductor films 1 and the display element units 2, there may be provided for example an unrepresented planarizing layer, if necessary. Also for the semiconductor film 1 and the display element unit 2 thus divided into plural areas, wirings in matrix have to be prepared for electrical connection.

Also in FIGS. 3A and 3B, an image forming switching element 111 corresponds to a display element 21 and the image forming switching circuit unit 11 is divided into plural areas, but it is also possible to position, in discrete manner, integrated switching circuit blocks each having plural switching elements and to drive plural pixels through wirings between the pixels and the integrated switching circuit block. In an extreme case, there may be provided a circuit film having a switching element 111 for each pixel.

Such configuration of dividing the semiconductor film 1 bearing the switching circuit unit or the display element unit 2 into plural units is particularly effective in case the dimension of the display apparatus is large.

(Fourth Embodiment)

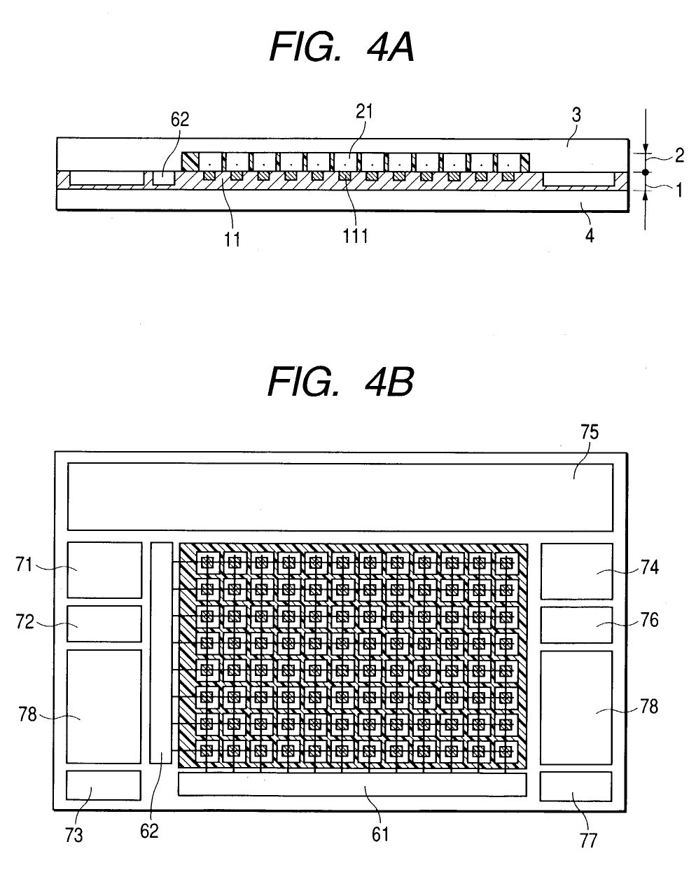

FIGS. 4A and 4B are respectively a cross-sectional view and a plan view, showing a fourth embodiment of the present invention, wherein components equivalent to those in FIGS. 1A through 3B are represented by like numbers and will not be explained further. In the present embodiment, in addition to the scan line drive circuit 62 and the data line drive circuit 61 in the second embodiment, there are formed, on a same semiconductor film 1, a processor 71, a memory 72, an image processing circuit 73, a wireless communication circuit 74, a solar cell 75, a secondary battery 76, an external input/output circuit 77, a speaker 78 etc. These constituents are electrically connected by unrepresented wirings, so that most of the peripheral circuit units necessary for the display apparatus is formed on the same semiconductor film 1.

These peripheral circuit units can be formed by a known method on the semiconductor film 1. Particularly a circuit requiring a high speed such as the processor 71 is preferably formed on a single-crystal semiconductor film. In FIGS. 4A and 4B, the peripheral circuit units are formed on a same semiconductor film 1, but it is also possible to all these peripheral circuit units or a part thereof on dived semiconductor films. In particular, it is preferable to form the solar cell 75, the secondary battery 76, the speaker 78 etc. in a thin film form on another substrate and to peel and combine these components. It is furthermore possible to form a part of the peripheral circuit units in another layer of the semiconductor film.

Circuits constituting the peripheral circuits are not limited to those explained in the foregoing but may be suitably added or deleted according to the necessity. It is naturally possible also to suitably add other known components of a thin-film shape necessary for the display apparatus, such as a touch-panel digitizer, a sheet-shaped battery (including a fuel cell) and a sheet-shaped heat sink.

(Fifth Embodiment)

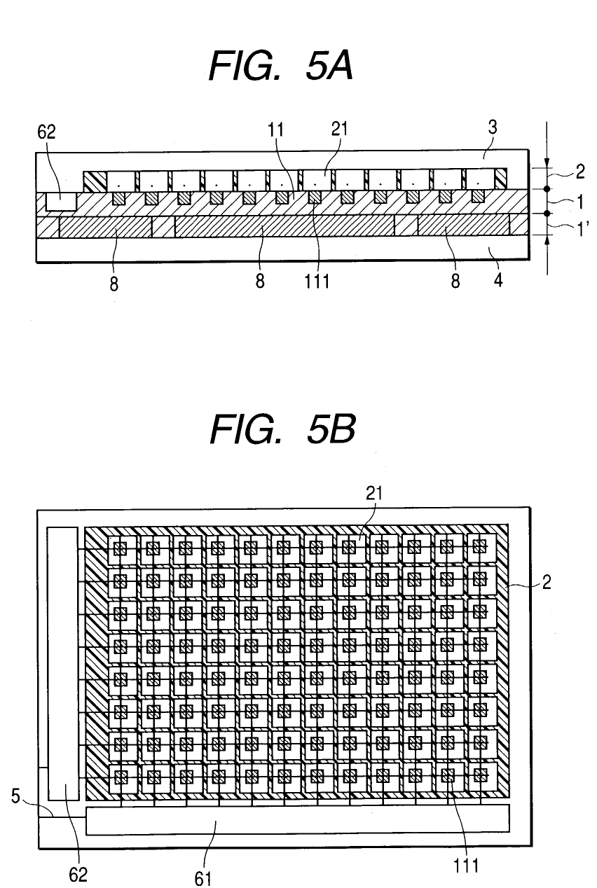

FIGS. 5A and 5B are respectively a cross-sectional view and a plan view, showing a fifth embodiment of the present invention, wherein components equivalent to those in FIGS. 1A through 4B are represented by like numbers and will not be explained further. In the present embodiment, there are laminated in succession a second semiconductor film 1′ having a peripheral circuit unit 8, a first semiconductor film 1 having an image forming switching circuit unit 11, a data line drive circuit 61 and a scan line drive circuit 62, and thereon a display element unit 2.

The second semiconductor film 1′ bearing the peripheral circuit unit 8 and the first semiconductor film 1 bearing the peripheral circuit units and the switching circuit unit 11 are interleaved by an unrepresented planarizing layer and are electrically bonded through contact holes or the like. However such configuration is not restrictive, and the planarizing layer may be dispensed with and the electrical bonding may be achieved, instead of the contact holes, for example by an anisotropic conductive film (ACF: a film having conductive paths showing conductivity only in the direction of thickness of the film and the adjacent conductive paths are mutually insulated electrically).

The peripheral circuit unit 8 includes a memory 72, a processor 71, a wireless communication circuit 74, an external input/output circuit 77 etc. as in the case shown in FIGS. 4A and 4B, and these circuits are formed on the second semiconductor film 1′. However, these circuits need not necessarily be positioned on the semiconductor film 1′. Also there are employed two semiconductor films bearing the circuit units, but there may be employed a larger number of layers if necessary. In such case, a planarizing layer or an interlayer insulation layer may be provided between the layers.

Also a part of the peripheral circuits is provided on the plane of the image forming switching circuit unit 11, but the image forming switching circuit unit 11 and the peripheral circuit units may be formed on different semiconductor films or on a same semiconductor film. In such case, however, it is preferred to form the image forming switching circuit unit 11, and the scan line drive circuit 62 and the data line drive circuit 61 for driving the switching circuit unit 11 on a same circuit film, in order to secure the bonding between the switching circuit unit and the drive circuits.

In the present embodiment, it is not required to position the peripheral circuits around the display element unit 2 or it is possible to reduce the peripheral circuits around the display element unit 2, so that a marginal area around the display element unit 2 can be minimized. Also in case the semiconductor film is provided in a laminate structure and the display element unit 2 is constituted by a transmissive liquid crystal display device, a light source such as a thin-film white EL is preferably provided between the first semiconductor film 1 and the second semiconductor film 1′.

(Sixth Embodiment)

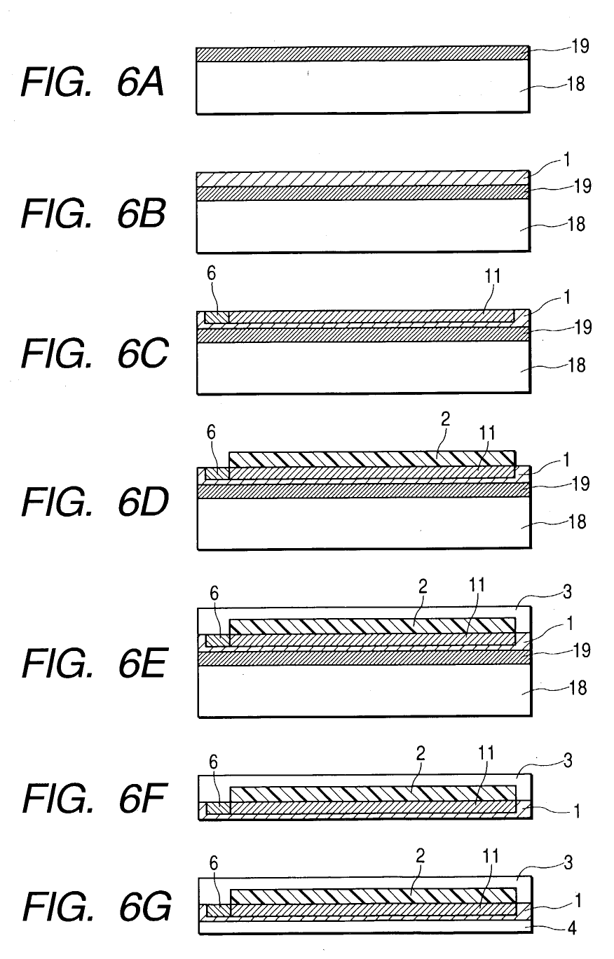

In the following there will be given a detailed explanation on a method for producing the display apparatus of the present invention. FIGS. 6A to 6G are views showing producing steps for a display apparatus of the present embodiment. At first, as shown in FIG. 6A, a separating layer 19 is formed on a semiconductor substrate 18. The semiconductor substrate 18 can be a single-crystal silicon wafer prepared by a CZ process, an MCZ process or an FZ process, a wafer with a hydrogen annealed surface or an epitaxial silicon wafer. In addition to the silicon wafer, there may also be employed a compound semiconductor substrate such as a GaAs substrate or an InP substrate.

On the other hand, the separating layer 19 may be formed by a method of utilizing a porous layer formed by anodizing, or a method of utilizing an ion implantation formed by ion implantation of hydrogen, nitrogen or a rare gas such as helium. The former method is effective because the formation of a porous layer generates a large crystal strain in the vicinity of an interface thereof, thereby facilitating separation. However, an extreme and abrupt increase in the porosity of the porous layer may results in an excessively large crystal strain, thereby eventually leading to a partial spontaneous peeling. It is therefore preferable to constitute the separating layer 19 with plural layer of different porosities, for example a layer of a higher porosity and a layer of a lower porosity from the side of the semiconductor substrate.

Also if a strain is transmitted to the surface of the porous layer, there may results a detrimental influence on the quality of a semiconductor film to be grown on the porous layer as will be explained later. For this reason, there may be employed a three-layered structure formed by a layer of a lower porosity, a layer of a higher porosity and a layer of a lower porosity from the side of the semiconductor substrate. The layer of the higher porosity may have a porosity from 10 to 90%, while the layer of the lower porosity may have a porosity from 1 to 70%. The layers with different porosities may be formed by changing a current density in the anodizing operation, or a kind or a concentration of an anodizing solution.

In case of forming the porous layer by anodizing, it is preferable, prior to growing a semiconductor film 1 on the separating layer 19 constituted by such porous layer, to execute a protective film forming process for forming a protective film such as a nitride film or an oxide film in the interior of the pores of the porous material, or a heat treatment process at 800 to 1000° C. in a hydrogen-containing atmosphere. It is also preferred to execute these steps, namely to form the protective film and to execute the heat treatment process.

It is also preferred to execute, after the heat treatment step, to execute a second heat treatment step at a higher temperature within a range from 900° C. to a melting temperature. For example, the first heat treatment step is executed at 950° C., and the second heat treatment step is executed at 1100° C. These steps execute sealing of pores on the surface of the porous layer. The formed porous layer has fine pores extending substantially vertically to the surface of the substrate, and maintains the crystallinity of the original substrate. The porous layer may have a thickness within a range from several hundred micrometers to about 0.1 μm.

Then, as shown in FIG. 6B, a semiconductor film 1 is deposited on the separating layer 19. The semiconductor film 1 can be formed by a known film forming method such as CVD, MBE or sputtering. In case of growing the semiconductor film 1 by CVD, it is preferably to maintain a low growing rate of 20 nm/min or less to a predetermined thickness (for example 10 nm). Since the porous layer maintains the crystallinity, the semiconductor film can be epitaxially grown thereon.

The semiconductor film 1 can be formed by a single-crystal silicon film, or a compound semiconductor film such as of GaAs, InP or GaN. In case the semiconductor film 1 is constituted by single-crystal silicon, there may be added, as a raw material gas, SiH₂Cl₂, SiHCl₃, SiCl₄, SiH₄, or HCl.

Then, as shown in FIG. 6C, a switching circuit unit 11 and a peripheral circuit unit 6, constituted by circuit elements or integrated circuits, are formed on the semiconductor film 1. The switching circuit unit 11 and the peripheral circuit unit 6 respectively correspond to the image forming switching circuit unit 11 and the peripheral circuit unit 6 shown in FIGS. 1A to 5B. These circuit elements or integrated circuits can be formed by a known process for preparing various devices. The switching circuit unit 11 can be formed by a known circuit, for example suitable combinations of MOSFET and capacitors.

Then, as shown in FIG. 6D, a display element unit 2 is formed on the semiconductor film 1 bearing the switching circuit unit 11 etc. Each display element 21 in the display element unit 2 is constituted, through not illustrated, by an upper electrode, a display element film and a lower electrode, and the switching elements in the switching circuit unit 11 are respectively connected to the respective lower electrodes. As explained in the foregoing, the display element unit 2 can utilize a known display element structure such as a liquid crystal display, an organic EL display, an inorganic EL display, an electrochromic display, an electrophoretic display or a twisting ball display.

Then, as shown in FIG. 6E, an upper protective film 3 is formed for protecting the display element unit 2. The upper protective film 3 may be formed by glass, but is preferably formed by a plastic material. The upper protective film 3 can be formed by adhering a polymer sheet, or by coating a polymer dissolved in an organic solvent followed by sintering.

Then, as shown in FIG. 6F, the semiconductor film 1 having the circuit unit, and the display element unit 2 and the upper protective film 3 formed thereon are peeled and separated at the separating layer 19, thereby preparing the display element including the circuit film. In case a porous layer is employed as the separating layer 19, there may be employed a separating method, as disclosed in Japanese Patent Application Laid-open No. 9-312349, of mechanical peeling by applying a tensile, compressing or shearing force to an area to be separated while holding a member with a vacuum chuck or the like, or a method of separation by the application of an ultrasonic vibration or a local heating.

However, in view of preventing a damage to the circuit resulting from a local stress applied to the circuit at the separation, there is preferred a method of applying a fluid pressure. In case of applying a fluid pressure, a fluid constituted by a liquid or a gas is directed as a high pressure jet to a lateral face of the separating layer 19. As such liquid, there may be utilized water, an etching solution or alcohol. In case of using a liquid, an ultrasonic wave may be applied at the same time. Also as such gas, there can be utilized air, nitrogen gas or argon gas. It is also possible to utilize a substance containing solid particles or powder of ice, plastic pieces, an abrasive material etc. in the fluid.

It is also possible to achieve separation by applying a static pressure to the separating layer 19.

For applying a static pressure, there are required a closed space constituting member for forming a closed space surrounding at least a part of peripheries of the semiconductor substrate 18, and a pressure applying mechanism for applying a higher pressure in the closed space than the pressure in the outer space.

Fluid is capable of flowing even into a very small gap thereby elevating the internal pressure and applying an external pressure in a dispersed manner. Also it can achieve separation selectively in a most easily separable position, as an extreme pressure is not applied to a part. Such fluid-utilizing method is optimum for separating an entire thin film on which thin film devices (circuits) are already formed, as in the present invention.

After the separating step, a part of the separating layer 19 may remain in a member including the circuit film (such remaining part being called a separation residual layer). Such separation residual layer may be eliminated if necessary by polishing, grinding or etching. Also the heat treatment in the hydrogen-containing atmosphere etc. may be conducted without removing such residual film. Such separation residual film has a high resistance, and functions as a kind of SOI, thereby achieving a higher speed or a lower power consumption in the device, and can be utilized without elimination if permissible.

Finally, as shown in FIG. 6G, a lower protective film 4 for protecting the semiconductor film 1 is formed to complete a display apparatus. The lower protective film 4 can be formed, like the upper protective film 3, by adhering a polymer sheet or by coating and sintering a polymer dissolved in an organic solvent. The remaining semiconductor substrate 18 can be repeatedly used in the preparation of the member including the aforementioned circuit film.

In the present embodiment, the switching circuit unit 11 and the peripheral circuit unit 6 are formed on the semiconductor film 1, but it is also possible to form a processor 71, a memory 72, an image processing circuit 73, a wireless communication circuit 74, a solar cell 75, a secondary battery 76, an external input/output circuit 77, a speaker 78 etc. as in FIGS. 4A and 4B. Also the film to be deposited on the separating layer 19 is not limited to a semiconductor film but can be an insulating film such as of silicon oxide, and a circuit film may be constructed by forming for example an MIM element. It is also possible to deposit a semiconductor film on the insulating film and to construct the circuit film by forming a circuit element or an integrated circuit on such semiconductor film.

(Seventh Embodiment)

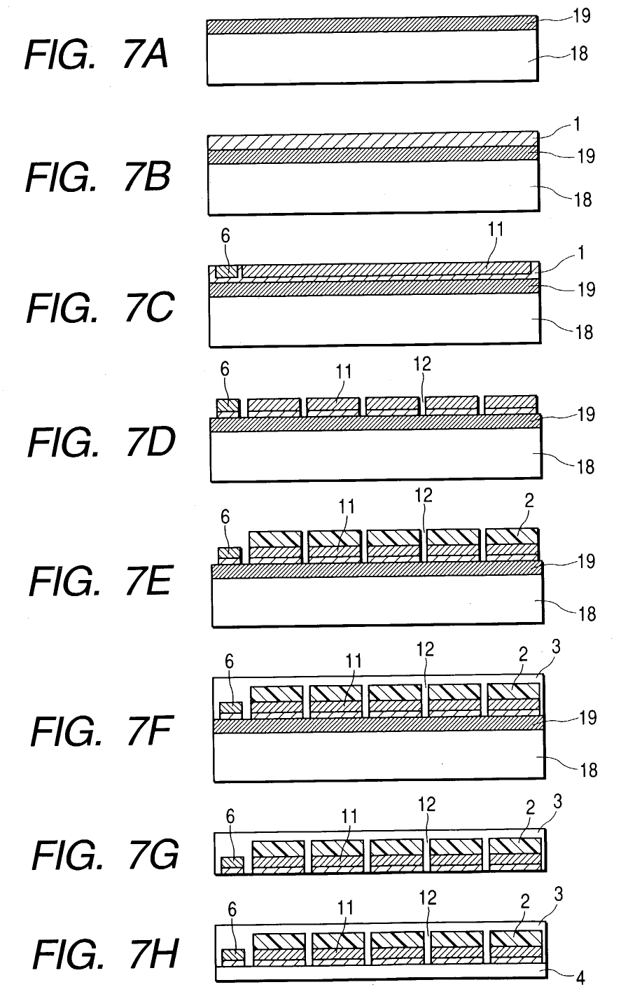

In the following there will be given a detailed explanation on another method for producing the display apparatus of the present invention as a seventh embodiment. FIGS. 7A to 7H are views showing producing steps for a display apparatus of the seventh embodiment. At first, a separating layer 19 is formed on a substrate (FIG. 7A), and a semiconductor film 1 is formed on the separating layer 19 (FIG. 7B). Then a switching circuit unit 11 and a peripheral circuit unit 6 are formed on the semiconductor layer 1 (FIG. 7C). These steps are similar to those shown in FIGS. 6A to 6C.

Then, as shown in FIG. 7D, a notched groove 12 is formed for every circuit or every block of an assembly of a certain number of the switching circuits 11 in order to form the semiconductor film 1 into plural assembly blocks. In this example, the peripheral circuit unit 6 and the switching circuit unit 11 are divided into plural blocks. The notched groove 12 can be formed by an ordinary dicing apparatus. There may also be employed etching laser ablasion, an ultrasonic cutter or a high pressure jet (for example water jet). In case of etching, there can be employed an etching solution such as HF+H₂O₂, HF+HNO₃, or an alkaline solution. In case of employing laser, there can be utilized a YAG laser, a CO₂ laser or an excimer laser.

The end of the notched groove 12 need not necessarily reach the separating layer 19, but preferably reaches the interior of the separating layer 19 or a vicinity of an interface between the semiconductor substrate 18 and the separating layer 19. However, in order to enable re-use of the semiconductor substrate 18, it is desirably so formed as not to reach the semiconductor substrate 18. Also in case the separating layer 19 includes a higher porosity layer and a lower porosity layer, the end of the notched groove 12 preferably reaches the interior of the higher porosity layer or a vicinity of an interface thereof.

Also prior to the formation of the notched groove 12, a LOCOS (local oxidation) or a mesa etching may be applied to a gap between chips to be separated into individual chips, thereby eliminating the semiconductor film between the chips.

An integral block of the switching circuit unit 11 thus formed into a chip is subjected to a bonding by unrepresented wirings in such a manner that all the elements are wired in a matrix. Such wirings can be formed, after a chip formation of the switching circuit unit 11, by planarizing a wiring forming portion with a plastic material or the like, and positioning metal wirings, an insulating layer etc. thereon by an ordinary semiconductor process or a printing process.

Then, as shown in FIG. 7E, a display element unit 2 is formed on each block of the divided image forming switching circuit unit 11, and an upper protective film 3 is formed on the display element unit 2 as shown in FIG. 7F. Then, as shown in FIG. 7G, the switching circuit unit. 11, the display element unit 2 and the upper protective film 3 formed integrally are separated from the semiconductor substrate 18, thereby forming a member including the circuit film, formed as a chip.

In this separation step, there may be employed, as explained in the sixth embodiment, a separating method of mechanical peeling, a method of applying an ultrasonic vibration or a local heating while holding a member with a vacuum chuck or the like. However, in view of preventing a damage to the circuit resulting from a local stress applied to the circuit at the separation, there is preferred a method of applying a fluid pressure.

A fluid pressure can be applied by directing a fluid constituted by a liquid or a gas as a high pressure jet to a lateral face of the separating layer 19, or by applying a static pressure to the separating layer. There may also be employed a method of injecting a high pressure fluid, constituted by a liquid or a gas, into the notched groove 12 or blowing such fluid to at least a part thereof. By blowing the liquid to the notched grooves around each chip, it is possible to achieve separation to each desired chip.

Finally, as shown in FIG. 7H, a lower protective film 4 is formed under the semiconductor film 1 to complete a display apparatus.

(Eighth Embodiment)

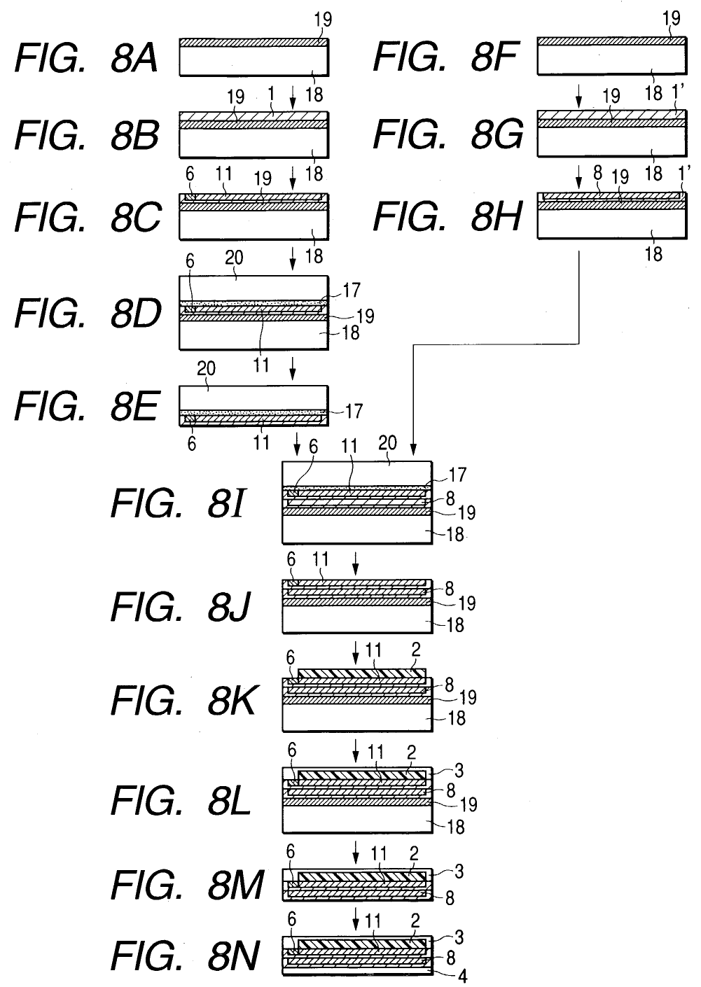

In the following there will be given a detailed explanation on still another method for producing the display apparatus of the present invention as an eighth embodiment. FIGS. 8A to 8N are views showing producing steps for a display apparatus of the seventh embodiment, wherein FIGS. 8A to 8E and FIGS. 8F to 8H show processes on different substrates.

At first, as shown in FIGS. 8A to 8C, a separating layer 19 is formed on a substrate 18, then a semiconductor film 1 is formed on the separating layer 19, and a switching circuit unit 11 and a peripheral circuit unit 6 are formed on the semiconductor layer 1. Then, as shown in FIG. 8D, a temporary substrate 20 is adhered by an adhesive layer 17 to the semiconductor film 1, and, as shown in FIG. 8E, the substrate 18 is separated at the separating layer 19. After the separation, the separation residual layer is removed by etching.

On the other hand, as shown in FIGS. 8F to 8H, a separating layer 19 is formed on a substrate 18, then a second semiconductor film 1′ is formed on the separating layer 19, and a peripheral circuit unit 8 is formed on the semiconductor film 1′.

Then, as shown in FIG. 8I, the semiconductor film 1′ shown in FIG. 8H is laminated on the semiconductor film 1 shown in FIG. 8E. This can be achieved for example by adhering the two semiconductor films with an adhesive material, or by adjoining the two semiconductor films by a heat treatment. Then, after elimination of the temporary substrate 20 as shown in FIG. 8J, the peripheral circuit unit 6, the switching circuit unit 11 and the peripheral circuit unit 8 of the two semiconductor films are electrically connected in necessary portions for example by contact holes.

Then, as shown in FIG. 8K, a display element unit 2 is formed on the image forming switching circuit unit 11, and, as shown in FIG. 8L, an upper protective film 3 is formed. Then the lower substrate 18 is separated at the separating layer 19 as shown in FIG. 8M, and finally a lower protective film 4 is formed as shown in FIG. 8N to complete a display apparatus.

For the peripheral circuit unit 6, a scan line drive circuit 62 and a data line drive circuit 61 shown in FIGS. 2A, 2B etc. are suitable since, if formed on the same substrate of the image forming switching circuit unit 11, such configuration is advantageous in achieving a high speed and a high reliability. For the peripheral circuit unit 8, there are suited non-drive circuits such as an image processing circuit, a processor or a memory as already shown in FIGS. 4A to 5B. Thus, the present embodiment allows to realize a flexible display system in more compact manner.

### EXAMPLES

In the following there will be explained examples of the present invention. The present inventors have prepared display apparatus explained in the foregoing embodiments and have made evaluations. In the following these will be explained as examples 1 and 2.

### Example 1

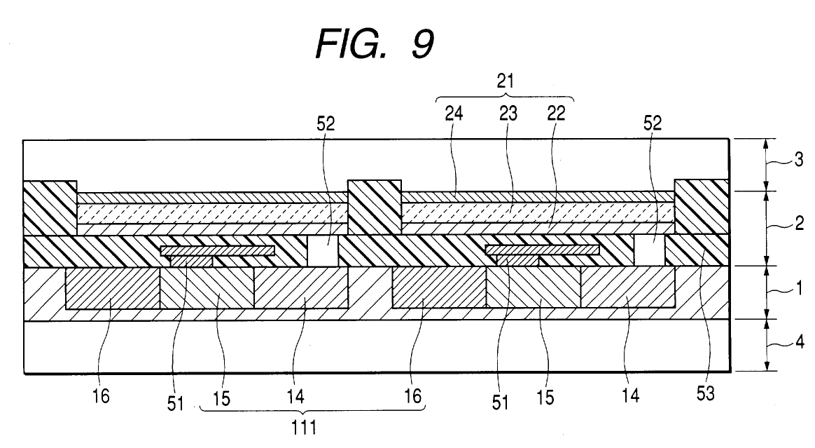

In an example 1, a display apparatus shown in FIGS. 2A and 2B were prepared by a process shown in FIGS. 6A to 6G. FIG. 9 shows a cross section of the prepared display apparatus. In this example, the display element unit 2 was constituted by an organic EL element. A switching element formed on the semiconductor film 1 at least included plural TFTs and a capacitor, and, in FIG. 9, there are shown two TFTs, namely a TFT 14 for driving the display unit and a TFT 15 for controlling a gate of the TFT 14. A lower electrode 22 of the organic EL element is electrically connected to a drain electrode of a TFT 14.

The organic EL element is basically constituted at least by a light emitting unit 23 positioned between a lower electrode 22 and an upper electrode 24. Also for improving the light emitting efficiency, there may be introduced an electron injection layer, an electron transport layer, a hole injection layer, a hole transport layer etc. Adjacent display elements 21 are preferably insulated electrically by an insulating layer 53.

Also the matrix wirings are so constructed, in the display element unit 2, that they are electrically connected with the circuit unit but are mutually insulated. After the formation of the display element unit 2, an upper protective film 3 is formed, and, after a separation at the separating layer 19, a lower protective film 4 is formed.

In the following there will be explained a method of producing the semiconductor film 1 with the switching circuit unit. At first, a p-type single-crystal silicon substrate 18 of a diameter of 300 mm and a specific resistivity of 0.01 Ω·cm was subjected to an anodizing in HF to form a separating layer 19 of a porous silicon layer (cf. FIG. 6A). The anodizing conditions were as follows:

current density: 7 mA/cm²

anodizing solution: HF:H₂O:C₂H₅OH=1:1:1

time: 11 minutes

porous silicon thickness: 12 μm.

The porous silicon layer was subjected to an adjustment of porosity in such a manner that a high-quality epitaxial silicon layer could be grown on the porous silicon layer and such porous silicon layer could be used as a separating layer. More specifically, the porosity was 20%.

The single-crystal silicon substrate was oxidized for 1 hour at 400° C. in an oxygen atmosphere. By such oxidation, the internal wall of the pores of the porous silicon was covered with a thermal oxide film. The surface of the porous silicon layer was treated with hydrofluoric acid to eliminate the oxide film on the surface of the porous silicon layer, while leaving the oxide film on the internal wall of the pores. Then, on the porous silicon layer, a single-crystal silicon layer was epitaxially grown by CVD to obtain a semiconductor film 1 of a thickness of 0.15 μm (cf. FIG. 6B). The growing conditions were as follows:

source gas: SiH₂Cl₂/H₂

gas flow rate: 0.5/180 l/min

gas pressure: 80 Torr

temperature: 950° C.

growth rate: 0.3 μm/min

Prior to the epitaxial growth, a heat treatment was conducted in a hydrogen-containing atmosphere, in order to seal the surface pores. In addition to such heat treatment, there may be added a small amount of silicon atoms for example by a raw material gas to complement the surface pore sealing.

The substrate thus prepared can be handled in a same manner as an ordinary epi wafer. It is only different in that it contains a porous layer under the epitaxially grown silicon layer.

On the semiconductor film 1 of the epitaxially grown silicon layer in a central square area, with a diagonal of 280 mm (11 inches), of the wafer, there were formed a switching circuit unit 11 for active matrix and a peripheral circuit unit 6 (cf. FIG. 6C). The switching circuit unit 11 is based, as already known, on plural MOSFETs (14, 15) and a capacitor 16.

The peripheral circuit unit 6 including a scan line drive circuit 62 and a data line drive circuit 61 was prepared by a process similar to that for the switching circuit unit 11. The scan line drive circuit 62 or the data line drive circuit 61 is a known circuit based on a CMOS circuit and formed by a combination of a shift register, analog switches, a level shifter, a buffer etc. Then bondings were made between the circuits and between the circuit and the wirings.

Then a display element unit 2 was formed on the switching circuit unit 11. At first an insulating layer 53 such as of polyimide was formed, and a matrix wiring 51 and contact holes 52 were suitably formed. A display element 21 at least includes a lower electrode 22, a light emitting portion 23 and an upper electrode 24, in which carriers are injected by a voltage application and light is emitted by a recombination of carriers in the light emitting portion 23.

In case of employing a low molecular material as the organic EL material, it is possible to form various layers by masked evaporation in vacuum, and the light emitting characteristics can be improved by adding an electron injection layer, an electron transport layer, a hole injection layer and a hole transport layer. Also in case of employing a high molecular material as the organic EL material, since it is generally soluble in an organic solvent, there can be used a printing method in the air.

After the formation of the display element unit 2, a PET sheet of a thickness of 100 μm was subjected to a formation of a heat-fusible adhesive layer and was adhered under heating as an upper protective layer 3.

Then a separation was executed at the porous silicon layer functioning as the separating layer 19 (cf. FIG. 6F). A water jet was employed for separation, but it is also possible to utilize an air jet, a nitrogen gas jet, another gas jet, a liquid jet other than water, a fluid jet containing ice or plastic particles or an abrasive, or to apply a static pressure with such materials. The porous silicon remaining on the circuit film was not removed, but it may also be removed.

On the other hand, the semiconductor substrate after the separation was subjected to a removal of a remaining porous layer, also a removal of a layer formed in the device process and remaining on an edge etc. if necessary and a re-polishing of the surface if necessary, and could be used again in a same process. It could also be used for another purpose, for example as a dummy wafer. Finally, thermoplastic polyimide was coated and sintered to form a lower protective film 4, whereby a display apparatus could be formed.

The completed display apparatus was used in a matrix image display by connecting a power source, a controller, a D/A converter etc., and a satisfactory display was obtained even in a bent state.

On the other hand, the semiconductor substrate after the separation was subjected to a removal of a remaining porous layer, also a removal of a layer formed in the device process and remaining on an edge etc. if necessary and a re-polishing of the surface if necessary, and could be used again in a same process. It could also be used for another purpose, for example as a dummy wafer. Since the layer used for forming the circuit and/or the integrated circuit is newly epitaxially grown each time, there was not observed a deterioration in the circuit characteristics or in the display characteristics of the display apparatus in repeated cycles.

### Example 2

The porous layer constituting the separating layer 19 was a single layer in the example 1, but it was formed by two layers of different porosities in the example 2. At first, a surface of the single-crystal silicon substrate was anodized under following conditions:

current density: 8 mA/cm²

anodizing solution: HF:H₂O:C₂H₅OH=1:1:1

time: 5 minutes

porous silicon thickness: 6 μm,

which was followed by:

current density: 33 mA/cm²

anodizing solution: HF:H₂O:C₂H₅OH=1:1:1

time: 80 seconds

porous silicon thickness: 3 μm.

In this manner there were formed, from the side of the single crystal silicon substrate, a higher porosity layer of a porosity of 45% and a lower porosity layer of a porosity of 20%. Thereafter a display apparatus was prepared in the identical manner as in the example 1.

The two-layered porous layer need not necessarily have a configuration of 6 μm/3 μm, and the thickness can be varied by changing the anodizing conditions. Also the anodizing solution need not be HF:H₂O:C₂H₅OH=1:1:1. Also ethanol may be replaced by another alcohol such as isopropyl alcohol. Since alcohol is used as a surfactant for preventing sticking of reaction bubbles to the wafer surface, it may be replaced by another surfactant, or it is also possible to remove the bubbles sticking to the surface by ultrasonic wave etc. instead of adding the surfactant.

The completed display apparatus was used in a matrix image display by connecting a power source, a controller, a D/A converter etc., and a satisfactory display was obtained even in a bent state.

On the other hand, the semiconductor substrate after the separation was subjected to a removal of a remaining porous layer, also a removal of a layer formed in the device process and remaining on an edge etc. if necessary and a re-polishing of the surface if necessary, and could be used again in a same process. It could also be used for another purpose, for example as a dummy wafer. Since the layer used for forming the circuit and/or the integrated circuit is newly epitaxially grown each time, there was not observed a deterioration in the circuit characteristics or in the display characteristics of the display apparatus in repeated cycles.

In the foregoing examples, the display apparatus was prepared employing an organic EL display as the display unit, but there can be utilized any other display method, such as liquid crystal display, inorganic EL display, electrochromic display, electrophoretic display or twisting ball display.

As explained in the foregoing, the present invention can realize a display apparatus of a high performance including a switching circuit, peripheral circuits etc. of which surfaces are protected for example with a plastic material without employing a substrate material. It is therefore possible to realize a lighter, thinner and more flexible display apparatus of a high image quality. Also since the process temperature in the formation of the image display unit is not restricted by the substrate material, there can be prepared a display apparatus of a high quality.

As may apparently widely different embodiments of the present invention can be made without departing from the spirit and scope thereof, it is to be understood that the invention is not limited to the specific embodiments thereof except as defined in the claims.

What is claimed is:

1. A display apparatus comprising a display element unit comprising by plural display elements and a semiconductor film separated at a separating layer formed on a substrate and including plural image forming switching elements for driving said display elements, said display element unit and said semiconductor film being mutually laminated.

2. A display apparatus according to claim 1, further comprising an upper protective film for protecting said display element unit and a lower protective film for protecting said semiconductor film, wherein at least either of said upper protective film and said lower protective film is translucent.

3. A display apparatus according to claim 2, wherein both of said upper protective film and said lower protective film are flexible.

4. A display apparatus according to claim 1, wherein a peripheral circuit unit is formed on the same semiconductor film.

5. A display apparatus according to claim 1, wherein the same semiconductor film is divided into plural areas by notched grooves.

6. A display apparatus according to claim 1, wherein said semiconductor film is formed by plural laminated semiconductor films, and a switching circuit unit or a switching circuit unit and a peripheral circuit unit is formed on one of the laminated semiconductor films while a peripheral circuit unit is formed on another of the laminated semiconductor films.

7. A display apparatus according to claim 1, wherein said semiconductor film is a single-crystal silicon layer.

8. A display apparatus according to claim 1, wherein said separating layer is a porous silicon layer.

9. A display apparatus according to claim 1, wherein said display element is a liquid crystal display element, an organic EL display element, an inorganic EL display element, an electrophoretic display element, a twisting ball display element, or an electrochromic display element.

10. A display apparatus according to claim 1, wherein said peripheral circuit unit comprises a scan line drive circuit and a data line drive circuit for selecting said display elements, a processor, a memory, an image processing circuit, a wireless communication circuit, a solar cell, a secondary battery, an external input/output circuit, or a speaker.

11. A method for producing a display apparatus comprising a step of forming a semiconductor film on a substrate having a separating layer, a step of forming an image forming switching element on said semiconductor film, a step of forming an image display unit on said semiconductor film, a step of forming an upper protective film on said image display unit, a step of peeling and separating said semiconductor film, said image display unit and said upper protective film from said substrate at said separating layer, and a step of forming a lower protective film on a side of said semiconductor film.

12. A method for producing a display apparatus comprising a step of forming a semiconductor film on a substrate having a separating layer, a step of forming an image forming switching element and a peripheral circuit unit on said semiconductor film, a step of forming an image display unit on said semiconductor film, a step of forming an upper protective film on said image display unit, a step of peeling and separating said semiconductor film, said image display unit and said upper protective film from said substrate at said separating layer, and a step of forming a lower protective film on a side of said semiconductor film.

13. A method for producing a display apparatus comprising a step of forming a semiconductor film on a substrate having a separating layer, a step of forming an image forming switching element or an image forming switching element and a peripheral circuit unit on said semiconductor film, a step of forming notched grooves on said semiconductor film thereby dividing the semiconductor film into plural areas, a step of forming an image display unit in each divided area of said semiconductor film, a step of forming an upper protective film on said image display unit, a step of peeling and separating said semiconductor film, said image display unit and said upper protective film from said substrate at said separating layer, and a step of forming a lower protective film on a side of said semiconductor film.

14. A method for producing a display apparatus comprising a step of forming a first semiconductor film on a first substrate having a first separating layer, a step of forming a circuit unit including at least an image forming switching element on said first semiconductor film, a step of adhering a temporary substrate to said first semiconductor film, a step of separating said first substrate at said separating layer, a step of forming a second semiconductor film on a second substrate having a second separating layer, a step of forming a peripheral circuit unit on said second semiconductor film, a step of adjoining the first semiconductor film on said temporary substrate and the second semiconductor film of said second substrate, a step of separating said temporary substrate, a step of forming an image display unit on said first semiconductor film after the separation of the temporary substrate, a step of forming an upper protective film on said image display unit, a step of separating said second substrate at said second separating layer, and a step of forming a lower protective film on a side of said semiconductor film.

15. A method of producing a display apparatus according to any of claims 11 to 14, wherein said separating step is executed by injecting a fluid which is a liquid or a gas into said separating layer.
